(19) United States
(12) Patent Application Publication
(10) Pub. No.: US 2002/0187627 A1
(43) Pub. Date: Dec. 12, 2002

(54) Method of fabricating a dual damascene structure

(76) Inventor: Yu-Shen Yuang, Miao-Li City (TW)

Correspondence Address: NAIPO (NORTH AMERICA INTERNATIONAL PATENT OFFICE), P.O. BOX 506, MERRIFIELD, VA, 22116, US

(21) Appl. No.: 09/875,503

(22) Filed: Jun. 6, 2001

(51) Int. Cl. H01L 21/4763; H01L 21/31; H01L 21/469

(52) U.S. Cl. 438/622; 438/634; 438/788

(57) ABSTRACT

A conducting layer is formed on a substrate and a first passivation layer is formed on the conducting layer. Following this, a first photo-chemical low dielectric constant (low-k) layer, a second passivation layer and a second low-k photo-chemical layer are formed in order on the substrate. Then, a first photolithographic process is performed to form a trench in the second low-k photo-chemical dielectric layer. A first etching process is performed to remove portions of the second passivation layer not covered by the second low-k photo-chemical layer down to the surface of the first low-k photo-chemical layer. Subsequently, a second photolithographic process is performed to form a via hole in the first low-k photo-chemical layer. Finally, a second etching process is performed to remove portions of the first passivation layer not covered by the first low-k photo-chemical layer down to the surface of the conducting layer.

### BACKGROUND OF THE INVENTION

1. Field of the Invention

The present invention relates to a method of fabricating a dual damascene structure, and more particularly, to a method of using low dielectric constant (low-k) photo-chemical materials to fabricate a dual damascene structure to simplify the dual damascene process.

2. Description of the Prior Art

A dual damascene process is a method of forming a conductive wire coupled with a via plug in a dielectric layer. The dual damascene structure, comprising a trench and a via hole, is used to connect devices and wires in a semiconductor wafer and is insulated with other devices by the inter-layer dielectrics (ILD) around it. As integrated circuit technology advances, improving the yield of the dual damascene structure, simplifying the process flow and reducing the production cost are important issues in the manufacturing process of integrated circuits at the present time.

Please refer to FIG. 1 to FIG. 7. FIG. 1 to FIG. 7 are schematic diagrams of a method of fabricating a dual damascene structure according to the prior art. As shown in FIG. 1, a semiconductor wafer 10 comprises a substrate 12, a conducting layer 14 positioned on a predetermined region of the surface of the substrate 12, and a passivation layer 16 of silicon nitride positioned on the conducting layer 14. Since the other elements positioned on the substrate 12 are not the concerning parts in the dual damascene process, they are not shown in FIG. 1 and in other figures. Furthermore, the semiconductor wafer 10 comprises a low-k layer 18, a passivation layer 20, a low-k layer 22 and a hard mask layer 24 positioned respectively on the surface of the passivation layer 16.

The low-k layers 18 and 22 are normally formed of spin-on-coating (SOC) low-k materials, such as HSQ or FLARE™, functioning to form the dual damascene structure therein to reduce the RC delay between the metal wires. But many of the low-k materials (especially the organic low-k materials) are fragile. Therefore denser materials, such as silicon nitride, are chosen to form the passivation layer 20 on the low-k layer 18 to harden the low-k layer 18. Similarly, another passivation layer is required to cover the low-k layer 22. The hard mask layer 24 covering the low-k layer 22 functions not only as the passivation layer but also as an etching mask in a later process. The hard mask layer 24 is composed of silicon nitride or silicon oxy-nitride.

As shown in FIG. 2, after the stacked structure shown in FIG. 1 is completed, a photolithographic and etching process is performed to form an opening 25 in the hard mask layer 24 to connect to the surface of the low-k layer 18, the opening 25 defining patterns for forming a trench of the dual damascene structure. Following this, as shown in FIG. 3, a photoresist layer 26 is coated on the surface of the semiconductor wafer 10. Another photolithographic process is performed to form an opening 27 penetrating through the photoresist layer 26 down to the surface of the low-k layer 22. The opening 27 functions to define patterns for forming a via hole of the dual damascene structure, so the width of the opening 27 must be smaller than that of the opening 25. In addition, the opening 27 is positioned inside the opening 25, such that a self-aligned contact (SAC) etching technique is used thereafter to form the dual damascene structure.

As shown in FIG. 4, a first etching process, such as an anisotropic dry etching process, is performed along the opening 27 to remove portions of the low-k layer 22 and the passivation layer 20 not covered by the photoresist layer 26, forming an opening 28 connecting to the surface of the low-k layer 18. Thereafter, a resist stripping process is performed to completely remove the photoresist layer 26.

As shown in FIG. 5, a second etching process is performed using the passivation layers 20 and 16 as stop layers to simultaneously remove portions of the low-k layers 22 and 18 not covered by the hard mask layer 24. Following this, both the passivation layer 20 and the passivation layer 16 not covered by the hard mask layer 24 are removed. As a result, a trench 30 penetrating through the low-k layer 22 and the passivation layer 20, and a via hole 31 penetrating through the low-k layer 18 and the passivation layer 16 down to the conducting layer 14 are formed at the same time.

As shown in FIG. 6, a deposition process is then performed to form a barrier layer 32 on the semiconductor wafer 10. The barrier layer 32 is formed of silicon nitride to prevent diffusion of copper or tungsten from the conducting layer 14 into silicon. Alternatively, the barrier layer 32 can also be composed of composite materials such as silicon nitride/Ta/Ti/TiN to increase adhesion between the dual damascene structure and a conducting layer covering the dual the conducting layer thereafter. Following that, a dry etching process is performed to remove portions of the barrier layer 32 to expose the top of the conducting layer 14. Another conducting layer 34 is then formed on the barrier layer 32 to fill both the trench 30 and the via hole 31.

As shown in FIG. 7, a chemical mechanical polishing process is performed using the barrier layer 32 as an end-point to remove the conducting layer 34 positioned outside the trench 30 and the via hole 31, such that the remaining conducting layer 34 inside the trench 30 and the via hole 31 is aligned with the surface of the barrier layer 32 positioned outside the trench 30. Finally, a passivation layer 36, such as a silicon nitride layer, is formed on the surface of the semiconductor wafer 10 to complete the fabrication of the dual damascene structure.

In the prior art dual damascene process, the semiconductor wafer 10 is put in a photolithographic apparatus to perform the exposure and development processes to define patterns for the trench 30 and the via hole 31. After that, the etching processes are used along the defined patterns to form the trench 30 and the via hole 31. As the device integration shrinks, however, an aspect ratio of the trench 30 or the trench 30 increases. Since the process window is not sufficient, defining patterns in the photoresist layer is subject to the resolution limit of the optical exposure tools. In addition, while performing the etching processes to form the trench 30 and the via hole 31, the device profiles are easily affected due to the insufficient process window, thereby increasing difficulty in the dual damascene process.

### SUMMARY OF THE INVENTION

It is therefore a primary objective of the present invention to provide a method of forming a dual damascene structure on a semiconductor wafer to increase a resolution of the dual damascene structure.

It is another objective of the present invention to provide a method of forming a dual damascene structure on a semiconductor wafer to simplify the dual damascene process and reduce the production cost.

According to the claimed invention, a conducting layer is formed on a semiconductor wafer and a first passivation layer is formed on the conducting layer. Following this, a first low-k photo-chemical layer, a second passivation layer and a second low-k photo-chemical layer are formed respectively on the semiconductor wafer to cover the conducting layer. Then, a first photolithographic process is performed to form a trench in the second low-k photo-chemical layer. A first etching process is performed to remove portions of the second passivation layer not covered by the second low-k photo-chemical layer down to the surface of the first low-k photo-chemical layer. Subsequently, a second photolithographic process is performed to form a via hole in the first low-k photo-chemical layer. Finally, a second etching process is performed to remove portions of the first passivation layer not covered by the first low-k photo-chemical layer down to the surface of the conducting layer to complete the fabrication of the dual damascene structure.

It is an advantage of the present invention that the dual damascene structure is formed in the low-k photo-chemical materials. The low-k photo-chemical materials can provide a better resolution and are especially suitable for processes of 0.13 μm or less than 0.13 μm, thus improving qualities of the photolithographic processes. In addition, using the low-k photo-chemical materials to form the trench and the via hole only needs a conventional exposure process and a conventional development process, preventing problems resulting from the etching processes for forming the trench and the via hole in the prior art. Specifically, the present invention improves the electrical performance of the dual damascene structure, increases yields of the dual damascene process, effectively simplifies the dual damascene process and reduces the production cost.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 are schematic diagrams of a prior art method of fabricating a dual damascene structure.

FIG. 8 to FIG. 13 are schematic diagrams of a first embodiment of the present invention to form a dual damascene structure on a semiconductor wafer.

FIG. 14 to FIG. 17 are schematic diagrams of a second embodiment of the present invention to form a dual damascene structure on a semiconductor wafer.

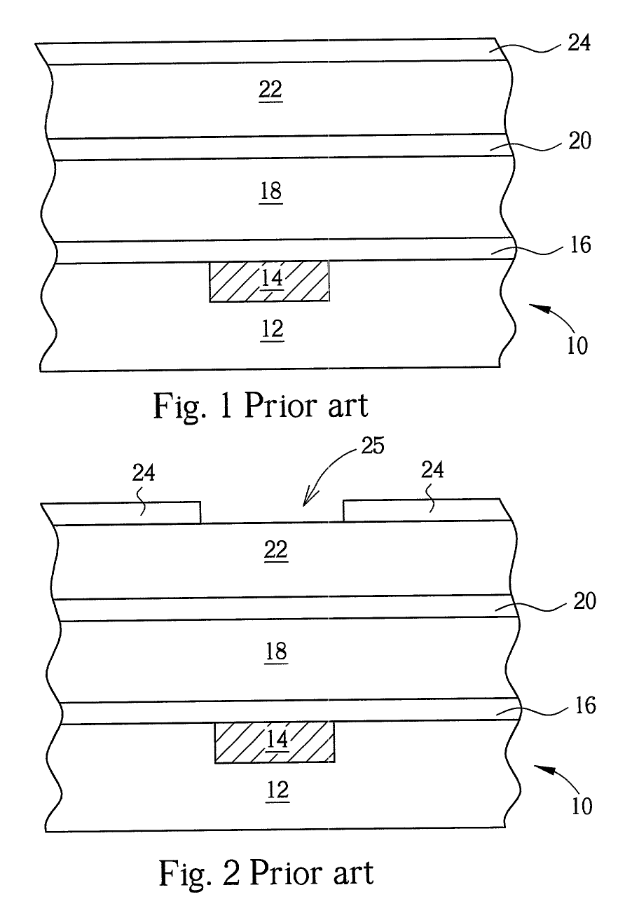

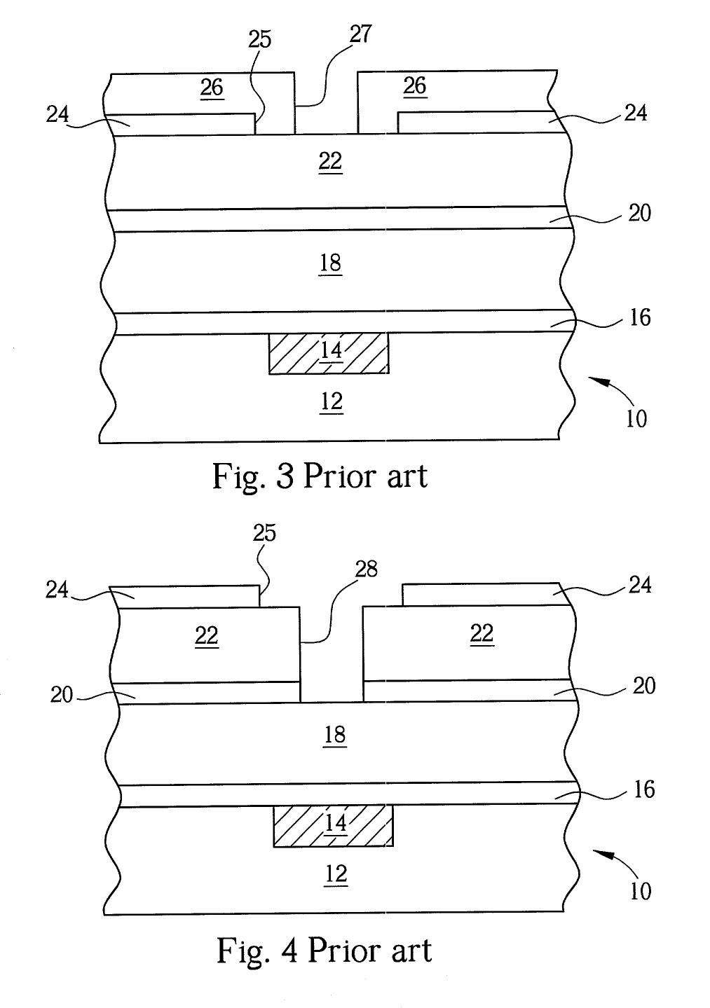

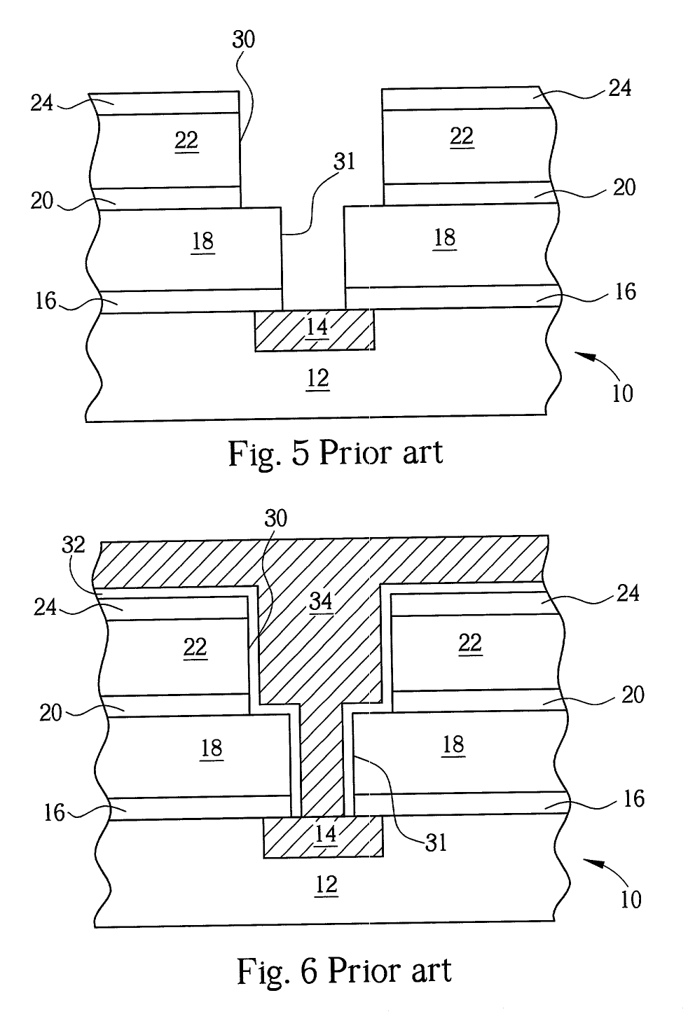

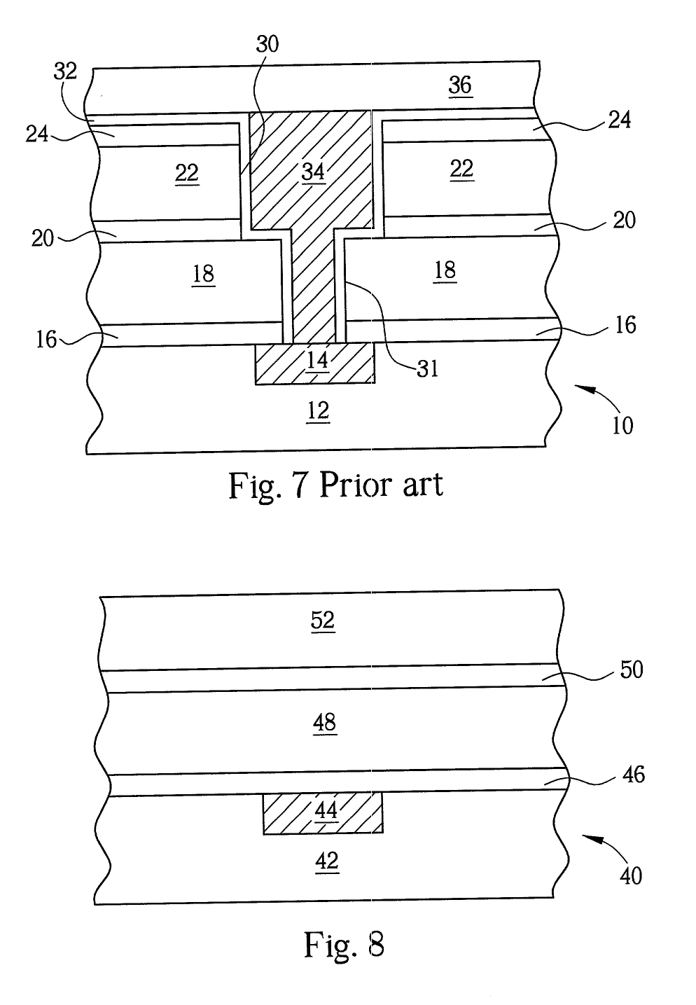

### DETAILED DESCRIPTION OF THE PREFERRED EMBODIMENT

Please refer to FIG. 8 to FIG. 13. FIG. 8 to FIG. 13 are schematic diagrams of a first embodiment of the present invention to form a dual damascene structure on a semiconductor wafer 40. In the first embodiment of the present invention, a trench-first dual damascene process is provided. As shown in FIG. 8, the semiconductor wafer 40 comprises a substrate 42, a conducting layer 44 positioned on a predetermined region of the surface of the substrate 42, and a passivation layer 46 positioned on the conducting layer 44. Therein, the conducting layer 44 is a copper wire, and the passivation layer 46 can be composed of silicon nitride, silicon oxy-nitride or silicon carbon. In addition, the semiconductor wafer 40 further comprises a low-k photo-chemical layer 48, a passivation layer 50 and another low-k photo-chemical layer 52 positioned in order on the surface of the passivation layer 46. Wherein, the passivation layer 50 positioned between the low-k photo-chemical layers 48 and 52 functions as an etching stop layer to define patterns for forming a trench of the dual damascene structure. In order to simplify the process flow, the passivation layer 50 can also be eliminated from the dual damascene structure, and a control of etching time is used so as to determine the etching end-point for forming the trench.

In a better embodiment of the present invention, both the low-k photo-chemical layers 48 and 52 are made of magnesia stabilized zirconia (MSZ) using spin coating. In other embodiments, both the low-k photo-chemical layers 48 and 52 may be made of yttria stabilized zirconia (YSZ) or other photoactive materials. The passivation layer 50 is made of fluorinated silicate glass (FSG). Alternatively, silicon nitride, silicon oxy-nitride or silicon carbon can also be applied to form the passivation layer 50.

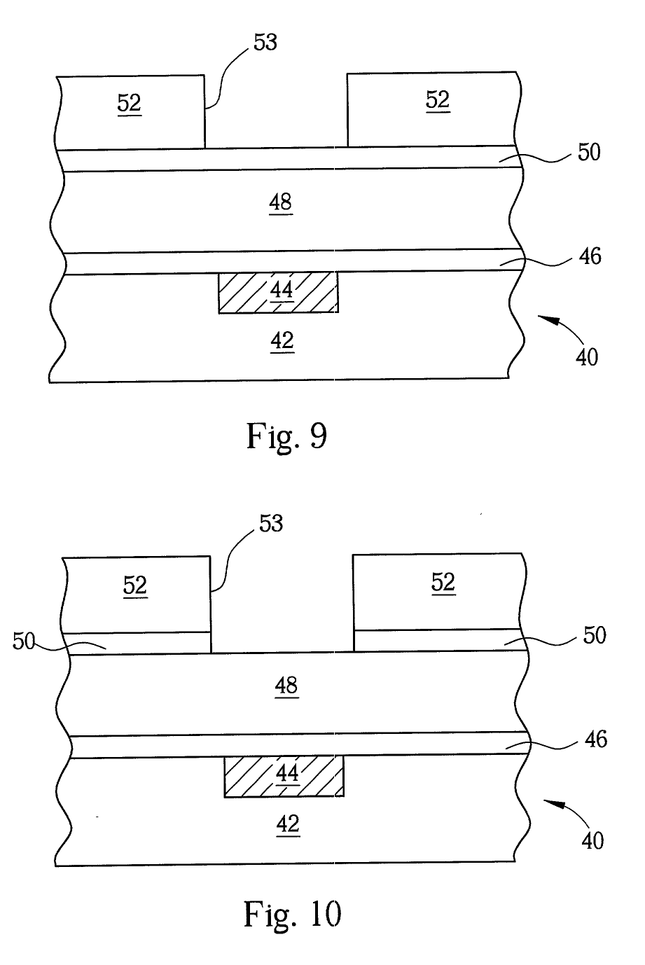

As shown in FIG. 9, a first photolithographic process is performed to form a trench 53 of the dual damascene structure in the low-k photo-chemical layer 52. The low-k photo-chemical layer 52, composing of MgO+ZrO₂, has good photo activity, hardness and thermal shock resistance. Thus, a hard mask layer and a photoresist layer are not required to be put on the low-k photo-chemical layer 52 before the first photolithographic process, as do in the prior art. Since patterns for forming the trench 53 can be directly defined in the low-k photo-chemical layer 52, the whole process flow of forming the trench 53 is effectively simplified. Additionally, both the cycle time and production cost are reduced. While performing the first photolithographic process, a conventional process flow is included. For example, the conventional process flow is achieved by a pre-bake at 90° C. for 1 minute, exposure to an electronbeam (EB) or ultraviolet (UV) light source, development in a tetramethyl ammonium hydroxide (TMAH) solution, and a post bake at 150° C. for 1 minute.

Following the above-mentioned steps, Si—O and S₁—CH₃ bonds are formed in the low-k photo-chemical layer 52, providing a low dielectric constant of 2.7 and showing good resistance to plasma treatment and copper.

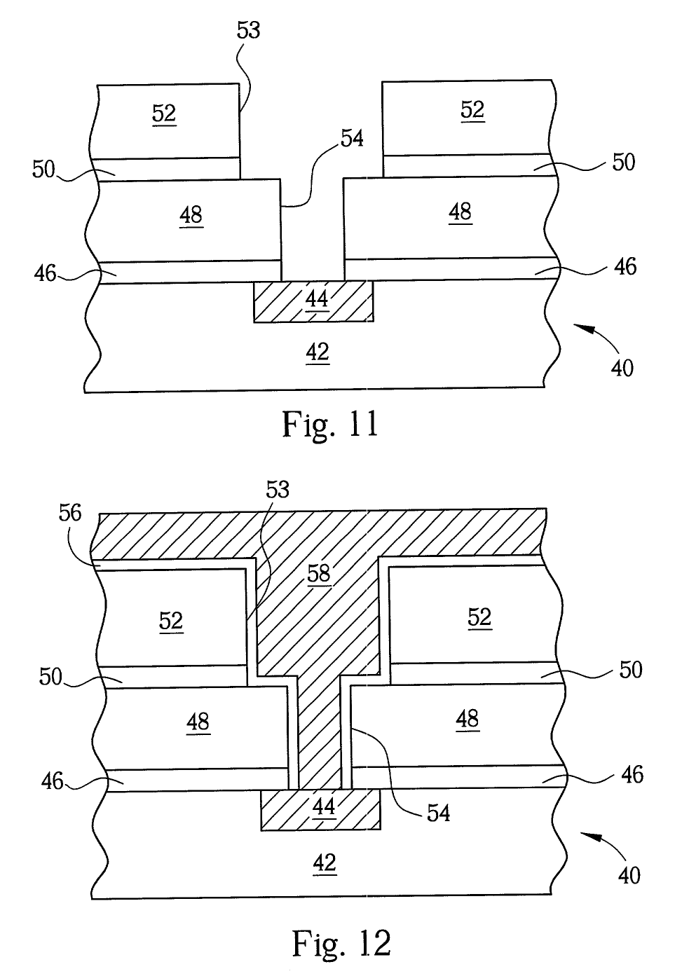

Subsequently, as shown in FIG. 10, a first etching process is performed. Using the low-k photo-chemical layer 52 as an etching mask, portions of the passivation layer 50 is removed to expose the surface of the low-k photo-chemical layer 48 in the first etching process. As shown in FIG. 11, a second photolithographic process is then performed to form a via hole 54 of the dual damascene structure in the low-k photo-chemical layer 48. Being similar to the first photolithographic process, the second photolithographic process also includes a pre-bake at 90° C. for 1 minute followed by exposure to an electron beam (EB) or ultraviolet (UV) light source, development in a tetramethyl ammonium hydroxide (TMAH) solution, and a post bake at 150° C. for 1 minute. Similarly, a second etching process is then required to remove portions of the passivation layer 46 not covered by the low-k photo-chemical layer 48 so as to connect the via hole 54 to the conducting layer 44.

Thereafter, as shown in FIG. 12, a deposition process is performed to form a barrier layer 56 on the semiconductor wafer 40. The barrier layer 56 is made of silicon nitride to prevent diffusion of copper from the conducting layer 44 into silicon. Alternatively, the barrier layer 56 can also be composed of composite materials such as silicon nitride/Ta/Ti/TiN to increase adhesion between the dual damascene structure and a conducting layer covering the dual the conducting layer thereafter. Following that, a dry etching process is performed to remove portions of the barrier layer 56 to expose the top of the conducting layer 44. Another conducting layer 58, such as a copper layer, is then formed on the barrier layer 56 filling both the trench 53 and via hole 54. Alternatively, the conductive layer 58 may also be consisted of other metal layers, forming a metal interconnection within the dual damascene structure.

As shown in FIG. 13, a chemical mechanical polishing process is performed. Using the barrier layer 32 as an end-point, the conducting layer 58 positioned outside the trench 53 and the via hole 54 is removed by the CMP. As a result, the remaining conducting layer 58 inside the trench 53 and the via hole 54 is aligned with the surface of the barrier layer 56 positioned outside the trench 53. Finally, a passivation layer 60, such as a silicon nitride layer, is formed on the surface of the semiconductor wafer 40 to complete the fabrication of the dual damascene structure.

Since the low-k photo-chemical materials can provide a better resolution, the dual damascene structure forming in the low-k photo-chemical materials according to the present invention can greatly improve certain qualities of the photolithographic processes. In addition, using the low-k photo-chemical materials to form the trench and the via hole only needs a conventional exposure process and a conventional development process, thereby preventing problems resulting from the extra photoresist layers and the etching processes for forming the trench and the via hole in the prior art.

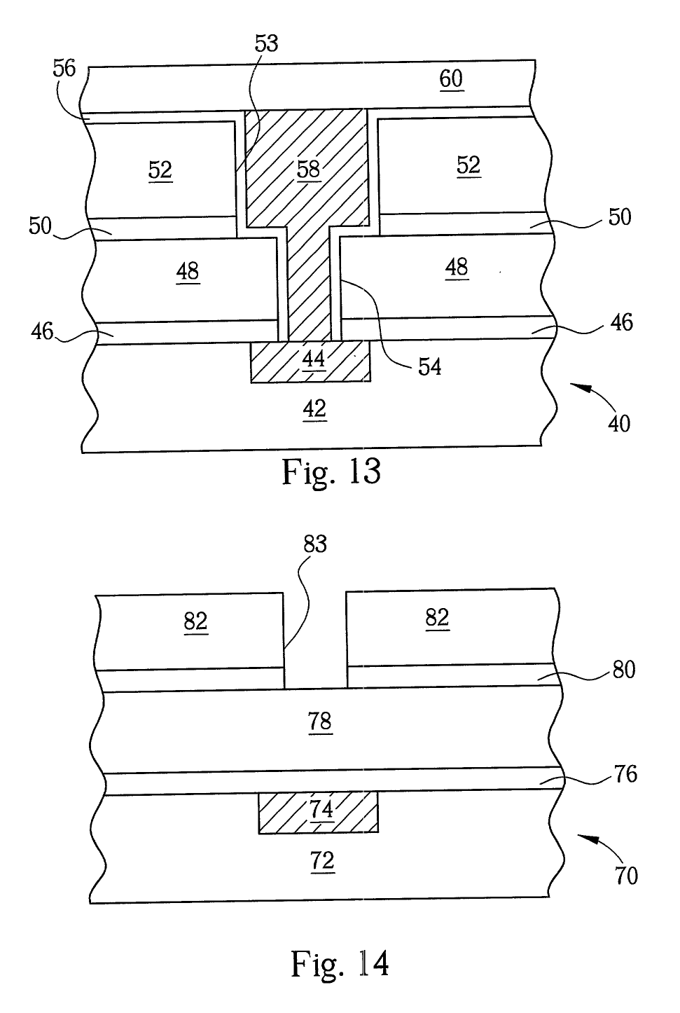

Please refer to FIG. 14 to FIG. 17 of schematic diagrams of a second embodiment of the present invention to form a dual damascene structure on a semiconductor wafer 70. In the second embodiment of the present invention, a via-first dual damascene process is provided. As shown in FIG. 14, the semiconductor wafer 70 comprises a substrate 72, a conducting layer 74 positioned on a predetermined region of the surface of the substrate 72, and a passivation layer 76 positioned on the conducting layer 74. In addition, the semiconductor wafer 70 further comprises a low-k photo-chemical layer 78, a passivation layer 80 and another low-k photo-chemical layer 82 positioned in order on the surface of the passivation layer 76. Selectively, the passivation layer 80 positioned between the low-k photo-chemical layers 78 and 82 can be eliminated from the dual damascene structure, so as to simplify the process flow.

After forming the stacked structure on the semiconductor wafer 70 as mentioned above, still referring to FIG. 14, a first photolithographic process is performed to form an opening 83 in the low-k photo-chemical layer 82. The opening 83 functions to define patterns for forming a via hole of the dual damascene structure. Subsequently, a first etching process is performed using the low-k photo-chemical layer 82 as an etching mask. During the first etching process, portions of the passivation layer 80 are removed to expose the surface of the low-k photo-chemical layer 78 and transfer the patterns of the via hole to the passivation layer 80.

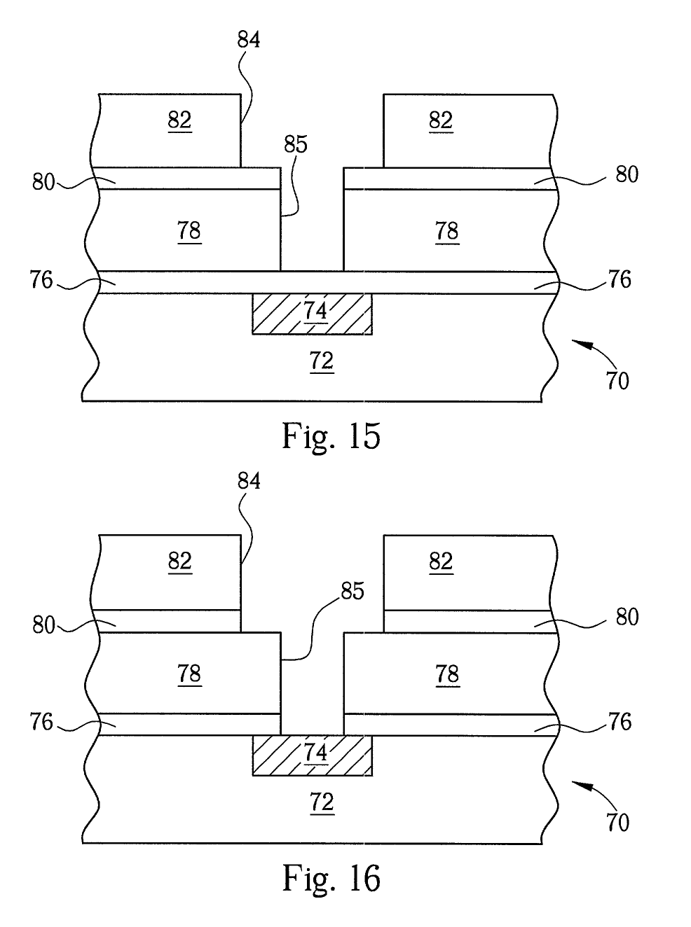

Following that, as shown in FIG. 15, a second photolithographic process is performed to form a trench 84 of the dual damascene structure in the low-k photo-chemical layer 82. Simultaneously, the patterns of the via hole is transferred from within the passivation layer 80 down to the low-k photo-chemical layer 78 so as to form a via hole 85 in the low-k photo-chemical layer 78 during the second photolithographic process. Then, as shown in FIG. 16, a second etching process is performed to remove portions of the passivation layer 76 not covered by the low-k photo-chemical layer 78 so as to connect the via hole 85 to the conducting layer 74.

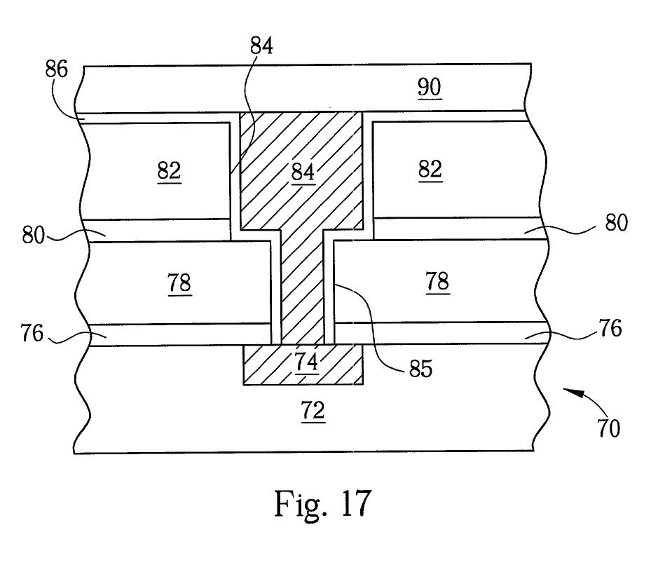

Thereafter, as shown in FIG. 17, a barrier layer 86 is deposited to cover the dual damascene structure and the low-k photo-chemical layer 82 around the dual damascene structure. The surface of the conducting layer 74 beneath the via hole 85 is then exposed. Subsequently, another conducting layer 88 is filled within both the trench 84 and via hole 85. A CMP process is then performed to polish the top of the conducting layer 88, aligning the remaining conducting layer 88 inside the trench 84 with the surface of the barrier layer 86 positioned outside the trench 84. Finally, a passivation layer 90 is formed on the surface of the semiconductor wafer 70 to complete the fabrication of the dual damascene structure.

According to the method described above, a phase-in method for pattern transferring is required to form the via hole in the via-first dual damascene process. Since the low-k photo-chemical materials, such as MSZ and YSZ, have excellent photoactivity, the etching processes for forming the profile of both the trench and the via hole, as in the prior art, are prevented. Thus, forming the dual damascene structure in the low-k photo-chemical materials according to the present invention effectively simplifies the whole fabrication process.

In contrast to the dual damascene process of the prior art, the present invention forms the dual damascene structure in the low-k photo-chemical materials. The low-k photo-chemical materials can provide a better resolution and are especially suitable for processes of 0.13 μm or less than 0.13 μm, thus improving qualities of the photolithographic processes. In addition, using the low-k photo-chemical materials to form the trench and the via hole only needs a conventional exposure process and a conventional development process, thereby preventing problems resulting from the photo and etching processes for forming the trench and the via hole in the organic photoresist layers in the prior art. Specifically, the present invention not only improves the electrical performance of the dual damascene structure and increases yields of the dual damascene process, but also effectively simplifies the dual damascene process and reduces the production cost.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of fabricating a dual damascene structure on a semiconductor wafer, the semiconductor wafer comprising a substrate, a conducting layer positioned on the substrate, and a first passivation layer positioned on the conducting layer, the method comprising:
forming a first dielectric layer, a second passivation layer, and a second dielectric layer, in order, on the semiconductor wafer to cover the conducting layer, both of the first dielectric layer and the second dielectric layer being formed of photo-chemical low dielectric constant materials;
performing a first photolithographic process to form a trench in the second dielectric layer;
performing a first etching process to remove regions of the second passivation layer not covered by the second dielectric layer down to the a surface of the first dielectric layer;
performing a second photolithographic process to form a via hole in the first dielectric layer; and
performing a second etching process to remove regions of the first passivation layer not covered by the first dielectric layer down to the a surface of the conducting layer to complete the fabrication of the dual damascene structure.

2. The method of claim 1 wherein the conducting layer comprises copper.

3. The method of claim 1 wherein the first passivation layer comprises silicon nitride, silicon-oxy-nitride, or silicon carbon.

4. The method of claim 1 wherein the second passivation layer comprises fluorinated silicate glass (FSG), silicon nitride, silicon-oxy-nitride, or silicon carbon.

5. The method of claim 1 wherein the photo-chemical low dielectric constant materials of both the first dielectric layer and the second dielectric layer of photo-chemical low dielectric constant materials comprise magnesia stabilized zirconia (MSZ) or yttria stabilized zirconia (YSZ).

6. A method of fabricating a dual damascene structure on a semiconductor wafer, the semiconductor wafer comprising a substrate, a conducting layer positioned on the substrate, and a first passivation layer positioned on the conducting layer, the method comprising:
forming a first dielectric layer, a second passivation layer and a second dielectric layer, in order, on the semiconductor wafer to cover the conducting layer, both of the first dielectric layer and the second dielectric layer being formed of photo-chemical low dielectric constant materials;
performing a first photolithographic process to form patterns of a via hole in the second dielectric layer;
performing a first etching process to remove regions of the second passivation layer not covered by the second dielectric layer down to the surface of the first dielectric layer to transfer the patterns of the via hole from within the second dielectric layer to the second passivation layer;
performing a second photolithographic process to form a trench in the second dielectric layer and simultaneously transfer the patterns of the via hole from within the second passivation layer to the first dielectric layer to form the via hole; and
performing a second etching process to remove regions of the first passivation layer not covered by the first dielectric layer down to the surface of the conducting layer to complete the fabrication of the dual damascene structure.

7. The method of claim 6 wherein the conducting layer comprises copper.

8. The method of claim 6 wherein the first passivation layer comprises silicon nitride, silicon-oxy-nitride, or silicon carbon.

9. The method of claim 6 wherein the second passivation layer comprises fluorinated silicate glass (FSG), silicon nitride, silicon-oxy-nitride, or silicon carbon.

10. The method of claim 6 wherein the photo-chemical low dielectric constant materials of both the first dielectric layer and the second dielectric layer of photo-chemical low dielectric constant materials comprise magnesia stabilized zirconia (MSZ) or yttria stabilized zirconia (YSZ).
